(19) United States
(12) Patent Application Publication
(10) Pub. No.: US 2026/0130034 A1
(43) Pub. Date: May 7, 2026

(54) DISPLAY MODULE, MANUFACTURING METHOD THEREOF, AND DISPLAY DEVICE THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Wen HAN, Wuhan, Hubei (CN); Zikang FENG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/687,864

(22) PCT Filed: Feb. 1, 2024
(86) PCT No.: PCT/CN2024/075140

§ 371 Date: Feb. 29, 2024

(30) Foreign Application Priority Data
Jan. 23, 2024 (CN) 202410093897.0

(51) Int. Cl. H10H 29/80; H10H 29/01; H10H 29/855

(52) U.S. Cl. CPC H10H 29/842; H10H 29/034; H10H 29/8552

(57) ABSTRACT

The present application discloses a display module, a manufacturing method thereof, and a display device thereof. The display module includes a display panel, a cover plate and a first bonding layer and a second bonding layer therebetween. The first bonding layer and the second bonding layer are at least disposed in corner sub-regions of the display module. The first bonding layer contacts the cover plate. A surface of a side of the second bonding layer near cover plate contacts a surface of a side of the first bonding layer away from cover plate. A curing rate of the first bonding layer is greater than or equal to a curing rate of the second bonding layer.

### FIELD OF INVENTION

The present application relates to a field of display technologies, especially to a display module, a manufacturing method thereof, and a display device thereof.

### BACKGROUND OF INVENTION

With the trend of electronic apparatuses pursuing the ultimate full-screen development, various display screens (for example, cell phones) are emerging endlessly in the market. In order to pursue the diversification of the appearance of display apparatus, the cover plate of the display screen has evolved from dual curved surfaces on the left and right sides to curved surfaces all around or even fully curved forms.

Curved surface screens include dual curved surface screens formed by the curvature of the two opposite sides of the display screen and quad-curved surface screens formed by the curvature of all four sides of the display screen. Quad-curved surface screens are usually formed by bonding the display panel with a cover plate having curved surfaces. In quad-curved surface screens, the positions where adjacent curved surfaces of the display screen intersect form Gaussian curved surfaces, which are prone to bubbles after bonding.

### SUMMARY OF INVENTION

The present application provides a display module, a manufacturing method thereof, and a display device thereof to ease a technical issue of a Gaussian curved surface of the conventional quad-curved surface screen easily has bubbles after bonding.

To solve the above solution, technical solutions provided by the present application are as follows:

The present application provides a display module, comprising a plane region and a curved surface region located on an outer periphery of the plane region, and the curved surface region comprising a plurality of side edge sub-regions located on a peripheral side of the plane region and corner sub-regions each of which is located between adjacent two of the side edge sub-regions, wherein the display module comprises:
a display panel;
a cover plate disposed on a side of the display panel; and
a first bonding layer located between the display panel and the cover plate, wherein the first bonding layer is at least disposed in the corner sub-regions, and the first bonding layer contacts the cover plate; and
a second bonding layer located between the display panel and the cover plate, wherein the second bonding layer is at least disposed in the corner sub-regions, and a surface of a side of the second bonding layer near the cover plate contacts the first bonding layer;
wherein a curing rate of the first bonding layer is greater than or equal to a curing rate of the second bonding layer.

The present application also sets forth a display module manufacturing method, comprising a plane region and a curved surface region located on an outer periphery of the plane region, and the curved surface region comprising a plurality of side edge sub-regions located on a peripheral side of the plane region and corner sub-regions each of which is located between adjacent two of the side edge sub-regions, wherein the display module manufacturing method comprises:
providing a cover plate;
forming a first bonding layer on a side of the cover plate away from a light exiting surface of the display module, and implementing a curing process to the first bonding layer, wherein the first bonding layer is at least disposed in the corner sub-regions;
providing a display panel, forming a second bonding layer on a side of the display panel near the light exiting surface of the display module, wherein the second bonding layer is at least disposed in the corner sub-regions; and
making a surface of the second bonding layer away from the display panel contacting a surface of the first bonding layer away from the cover plate, and implementing a curing process to the second bonding layer;
wherein a curing rate of the first bonding layer is greater than or equal to a curing rate of the second bonding layer.

The present application also sets forth a display device, comprising a display module, the display module comprising a plane region and a curved surface region located on an outer periphery of the plane region, and the curved surface region comprising a plurality of side edge sub-regions located on a peripheral side of the plane region and corner sub-regions each of which is located between adjacent two of the side edge sub-regions:
wherein the display module comprises:
a display panel;
a cover plate disposed on a side of the display panel; and
a first bonding layer located between the display panel and the cover plate, wherein the first bonding layer is at least disposed in the corner sub-regions, and the first bonding layer contacts the cover plate; and
a second bonding layer located between the display panel and the cover plate, wherein the second bonding layer is at least disposed in the corner sub-regions, and a surface of a side of the second bonding layer near the cover plate contacts the first bonding layer;
wherein a curing rate of the first bonding layer is greater than or equal to a curing rate of the second bonding layer.

### DESCRIPTION OF DRAWINGS

FIG. 1 is a schematic view of a Gaussian curved surface of a conventional quad-curved surface screen generating bubbles;

FIG. 2 is a schematic view of a first structure of a display module of the present application;

FIG. 3 is a schematic view of a second structure of the display module of the present application;

FIG. 4 is a first cross-sectional view along a cross-section MM in FIG. 3;

FIG. 5 is a second cross-sectional view along the cross-section MM in FIG. 3;

FIG. 6 is a schematic view of film layers of a display panel of the display module of the present application;

FIG. 7 is an exploded view of the display module of the present application;

FIG. 8 is a flowchart of the display module manufacturing method of the present application; and

FIGS. 9a to 9c are flowcharts of the display module manufacturing method of the present application.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when not specified to the contrary explanation, usually refer to the upper and lower states of the device in actual use or working conditions, specifically according to the direction of the figures in the drawings. Furthermore, “inner” and “outer” refer to the outline of the device.

In a current quad-curved surface screen, a display panel is bonded to a cover plate through a clear optical adhesive. The clear optical adhesive comprises an OCA adhesive. At the four corners of the quad-curved surface screen, there exist horizontally and vertically curved overlap regions. When the display panel and cover plate are fitted into the curved overlap region, they will be compressed. This curved overlap region is referred to as the Gaussian angle region, and the curved surface of the overlap region is termed the Gaussian curved surface. When the display panel completely enters the Gaussian angle region, the Gaussian curved surface of the Gaussian angle region can display, achieving a high screen ratio for the quad-curved surface screen. However, as the area of the display panel entering the Gaussian angle region increases, the compression experienced by the backplate and display panel also increases. With greater compression, the display panel is more prone to exhibiting noticeable wrinkles when adhered to the cover plate, and issues such as fractures in the metal wiring and inorganic layer within the display panel become more likely.

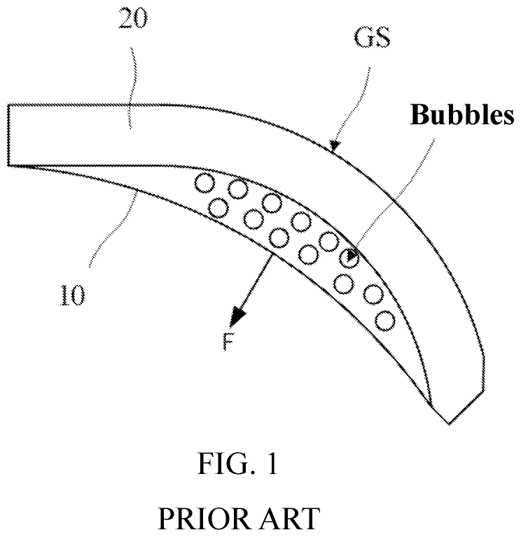

With reference to FIG. 1, FIG. 1 is a schematic view of a Gaussian curved surface of a conventional quad-curved surface screen generating bubbles. After the display panel 10 is bonded with a cover plate 20, the backplate and the display panel 10 suffer greater compression in the Gaussian angle region. Also, the backplate, serving as a supporting member for the display panel 10, has a higher elastic modulus such that the backplate generate a greater rebound force F. When the rebound force F is greater than an adhesive force of a clear optical adhesive between the display panel 10 and the cover plate 20, the display panel 10 separates from the cover plate 20 in the Gaussian angle region, resulting in bounce bubbles generated on the Gaussian curved surface GS.

Regarding the above technical issue, the present application sets forth a technical solution as follows.

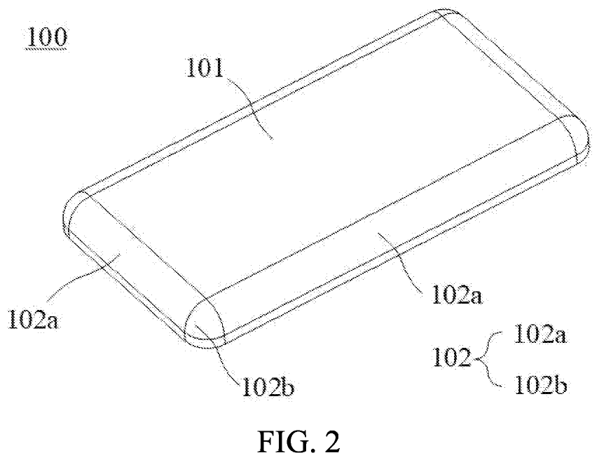

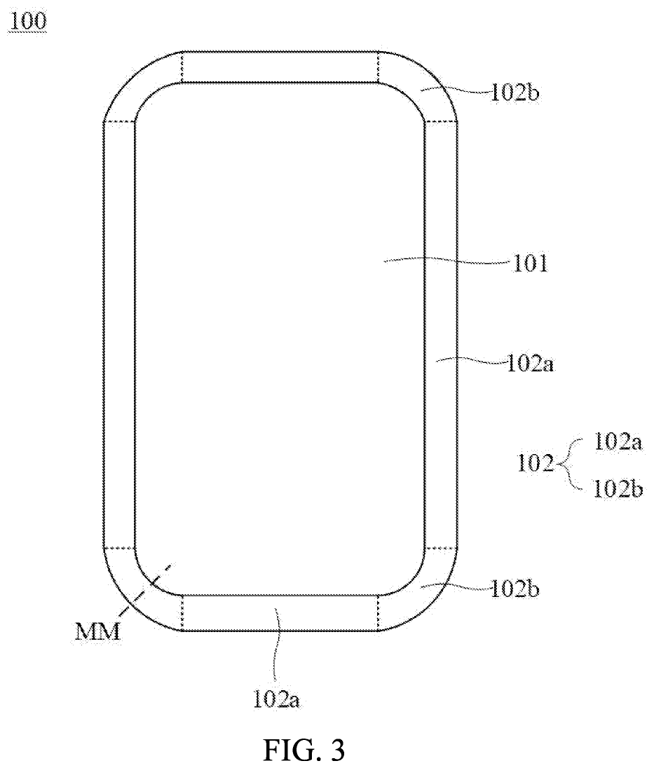

With reference to FIGS. 2 and 3, the present application provides a display module 100. The display module 100 comprises a plane region 101 and a curved surface region 102 located on an outer periphery of the plane region 101, and the curved surface region 102 comprises a plurality of side edge sub-regions 102a located on a peripheral side of the plane region 101 and corner sub-regions 102b each of which is located between located between adjacent two of the side edge sub-regions 102a. For example, in a structure of FIG. 3, the display module 100 comprises four side edge sub-regions 102a and four the corner sub-regions 102b, and a curved surface in the corner sub-region 102b is a Gaussian curved surface of the present application.

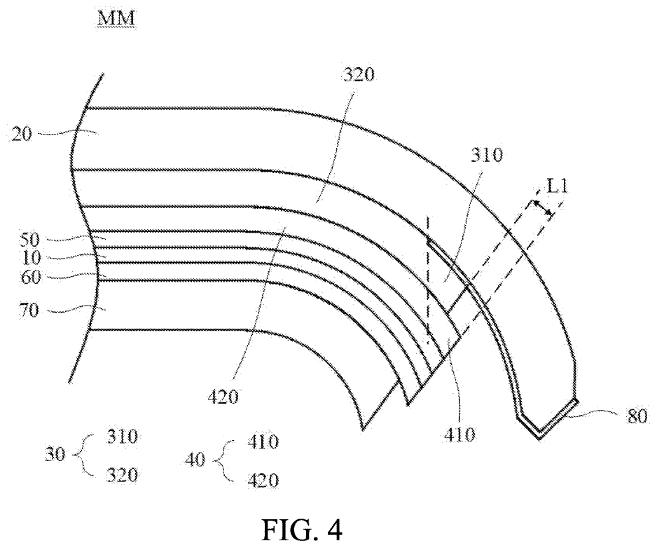

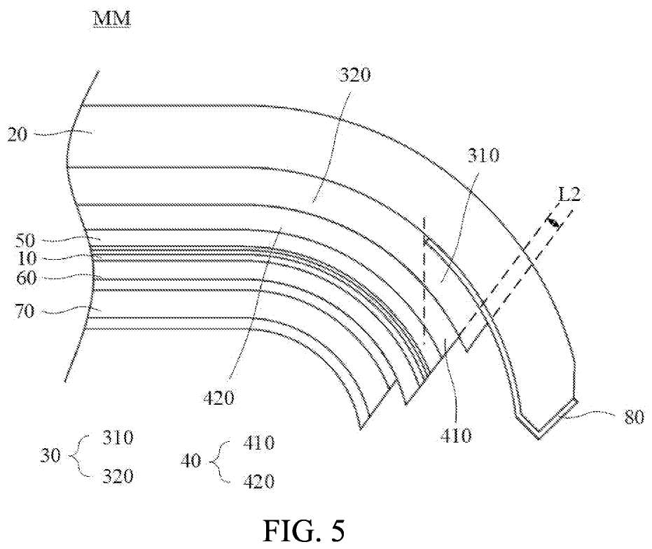

With reference to FIGS. 4 and 5, FIG. 4 is a first cross-sectional view along a cross-section MM in FIG. 3, FIG. 5 is a second cross-sectional view along the cross-section MM in FIG. 3.

In the present embodiment, the display module 100 comprises a display panel 10, the cover plate 20 and a first bonding layer 30 and a second bonding layer 40 located between the display panel 10 and the cover plate 20. The first bonding layer 30 and the second bonding layer 40 are disposed between the display panel 10 and the cover plate 20. Further, the first bonding layer 30 is disposed near the cover plate 20, and the second bonding layer 40 is disposed away from the cover plate 20.

In the present embodiment, the first bonding layer 30 is at least disposed in the corner sub-regions 102b. The first bonding layer 30 contacts the cover plate 20. The second bonding layer 40 is at least disposed in the corner sub-regions 102b. A surface of a side of the second bonding layer 40 near the cover plate 20 contacts the first bonding layer 30.

In the present embodiment, a curing rate of the first bonding layer 30 is greater than or equal to a curing rate of the second bonding layer 40.

The present application, disposing the first bonding layer 30 and the second bonding layer 40 between the display panel 10 and the cover plate 20and making a curing rate of the first bonding layer contacting the cover plate 20 greater than or equal to a curing rate of the second bonding layer away from the cover plate 20, increases a strength of the first bonding layer 30 such that a rebound force exerted by the first bonding layer 30 against a module structure in the corner sub-regions 102b is increased to ease an issue of bubbles easily generated on a Gaussian curved surface of a conventional quad-curved surface screen after bonding.

It should be explained that a curing rate of the present application is a curing degree inside the first bonding layer 30 and the second bonding layer 40. The greater the curing rate is, the greater a cohesion of material itself. Namely, an internal strength of the first bonding layer 30 is increased such that a rebound force exerted by the first bonding layer 30 against the module structure in the corner sub-regions 102b is increased, thereby avoiding the technical issue of bubbles occurring between the first bonding layer 30 and the cover plate 20.

It should be explained that the curing rates of the first bonding layer 30 and the second bonding layer 40 of the present application are also positively correlated with a modulus. The higher the curing rate is, the greater the modulus is. Namely, the present application can increase a modulus of the first bonding layer 30 such that a rebound force exerted by the first bonding layer 30 against the module structure in the corner sub-regions 102b is increased, thereby avoiding the technical issue of bubbles occurring between the first bonding layer 30 and the cover plate 20. The modulus of the present application can be a Young's modulus or a storage modulus.

It should be explained that because bubbles between the cover plate 20 and the display panel 10 only exist in the corner sub-regions 102b, the first bonding layer 30 and the second bonding layer 40 of the present application can be disposed in the corner sub-regions 102b. Alternatively, the first bonding layer 30 and the second bonding layer 40 of the present application can be disposed in the corner sub-regions 102b in the side edge sub-regions 102a. Alternatively, the first bonding layer 30 and the second bonding layer 40 of the present application can be disposed on an entire layer, only the first bonding layer 30 and the second bonding layer 40 of the present application can be disposed in the plane region 101 and the curved surface region 102. The following embodiment uses the first bonding layer 30 and the second bonding layer 40 disposed in the plane region 101 and the curved surface region 102 as an example for explanation.

It should be explained that material of the first bonding layer 30 of the present application comprises an ultraviolet curable optical adhesive, material of the second bonding layer 40 comprises one of an ultraviolet curable optical adhesive and a non-ultraviolet curable optical adhesive. For example, both the first bonding layer 30 and material of the second bonding layer 40 comprise an ultraviolet curable optical adhesive, then in a subsequent curing process, ultraviolet can be utilized to cure the first bonding layer 30 and the second bonding layer 40. Alternatively, material of the first bonding layer 30 comprises an ultraviolet curable optical adhesive, material of the second bonding layer 40 comprises a non-ultraviolet curable optical adhesive, for example, a thermal curing adhesive.

The technical solution of the present application will now be described with reference to specific embodiments.

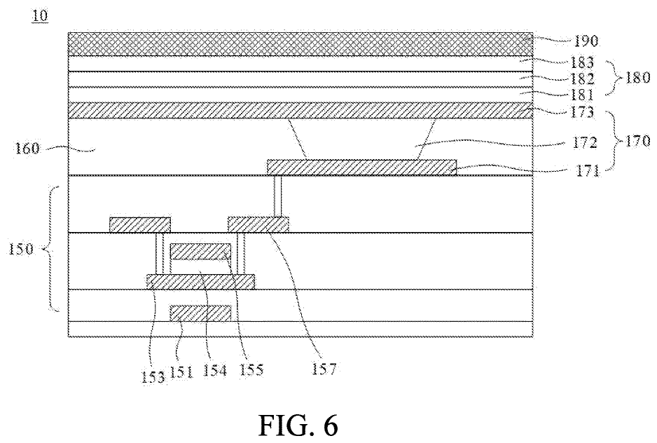

With reference to FIG. 6, FIG. 6 is a schematic view of the display panel 10 of the present application. The display panel 10 can comprise an underlay substrate 140, a driver circuit layer 150 disposed on the underlay substrate 140, a pixel definition layer 160 and a light emitting device layer 170 disposed on the driver circuit layer 150, an encapsulation layer 180 disposed on the pixel definition layer 160, and a touch layer 190 disposed on the encapsulation layer 180.

In the present embodiment, the underlay substrate 140 supports each layer disposed on the underlay substrate 140. When the display panel 10 is a bottom light emission display device or dual-surface light emission display device, it utilizes a transparent underlay substrate. When the display panel 10 is a top light emission display device, it can utilize a translucent or opaque underlay substrate and a transparent underlay substrate.

In the present embodiment, the underlay substrate 140 can be made of insulative material such as glass, quartz, or polymer resin. the underlay substrate 140 can be a rigid underlay or a bendable, foldable, or curled flexible underlay. An example of flexible material for a flexible underlay comprises polyimide (PI) but is not limited to polyimide (PI).

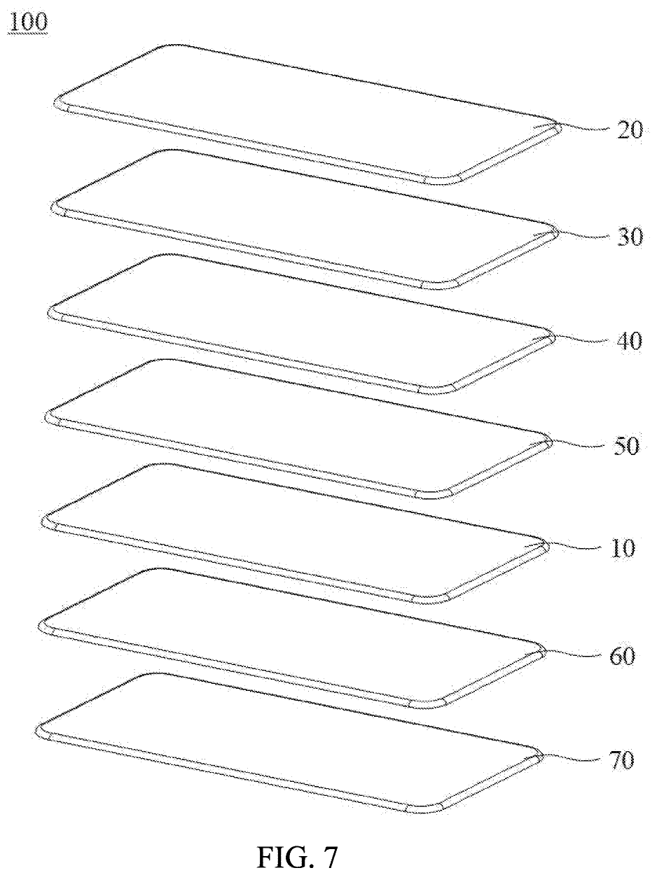

In the present embodiment, with reference to FIG. 6, the driver circuit layer 150 can comprise a plurality of thin film transistors. The thin film transistors can be etch block type, rear channel etch type, or are classified into structures such bottom gate thin film transistors, top gate thin film transistors, etc. according to locations of a gate electrode and an active layer, which has no specific limit. For example, thin film transistors as shown in FIG. 7 are top gate type thin film transistors. The thin film transistors can comprise a light shielding unit 151 disposed on a substrate, a buffer layer 152 disposed on the light shielding unit 151, an active layer 153 disposed on the buffer layer 152, a gate insulation layer 154 disposed on the active layer 153, a gate electrode layer 155 disposed on the gate insulation layer 154, an interlayer insulation layer 156 disposed on the gate electrode layer 155, a source and drain electrode layer 157 disposed on the interlayer insulation layer 156, and a planarization layer 158 disposed on the source and drain electrode layer 157. In the present embodiment, the interlayer insulation layer 156 can be disposed on an entire layer, or be the structure shown in FIG. 6 to be formed by the same mask process with the gate electrode layer 155. The structures of thin film transistors in FIG. 6 are only one example of the present application, thin film transistors of another type is also suitable for the present application.

In the present embodiment, with reference to FIG. 6, the light emitting device layer 170 can also comprise an anode layer 171 disposed on the planarization layer 158, a light emitting layer 172 disposed on the anode layer 171, and a cathode layer 173 disposed on the light emitting layer 172. The anode layer 171 comprises a plurality of anodes. The pixel definition layer 160 comprises a plurality of pixel apertures corresponding to the anodes, and each of the pixel apertures corresponds to an upper surface exposing one anode. The light emitting layer can comprise a plurality of light emitting pixels corresponding to the anodes.

In the present embodiment, with reference to FIG. 6, the encapsulation layer 180 covers the pixel definition layer 160, and continuously covers a plurality of pixel apertures and a plurality of light emitting pixels. The encapsulation layer 180 can at least comprise a first inorganic encapsulation layer 181, a first organic encapsulation layer 182, and a second inorganic encapsulation layer 183 laminated on the pixel definition layer 160.

In the present embodiment, with reference to FIG. 6, the touch layer 190 can comprise a first touch metal layer and a second touch metal layer disposed on the encapsulation layer 180 and an insulation layer disposed between the first touch metal layer and the second touch metal layer. The touch layer 190 provided by the embodiment of the present application can be mutual-capacitive or self-capacitive. Specifically, type and structure of the touch layer 190 can be selected according to actual demands.

In the present embodiment, with reference to FIG. 7, FIG. 7 is an exploded view of the display module 100 of the present application. The display module 100 further comprises a polarizer 50. The polarizer 50 can disposed between the display panel 10 and the second bonding layer 40. For example, the polarizer 50 can be disposed above the touch layer 190 in the display panel 10, which has no specific limit.

In the present embodiment, with reference to FIG. 7, the display module 100 further comprises a backplate layer 60 disposed on a side of the display panel 10 away from the cover plate 20. The backplate layer 60 is disposed on a non-light exiting side of the display module 100, and is configured to support the display panel 10. Material of the backplate layer 60 can comprise poly ethylene terephthalate (PET).

In the present embodiment, with reference to FIGS. 4, 5, and 7, the display module 100 further comprises a support function layer 70 disposed on a side of the backplate away from the cover plate 20. The support function layer 70 is configured to cooperate with the backplate layer 60 to support the display panel 10 and perform a heat dissipation function to the display panel 10. The support function layer 70 can comprise a plurality of sub-layers laminated, for example, it can comprise a buffer layer, a heat dissipation layer, and a metal layer. Material of the buffer layer comprises foam or poly ethylene terephthalate with large elastic deformation performance. Material of the heat dissipation layer comprises material with excellent thermal conductivity or heat dissipation performance such as graphite. Material of the metal layer comprises copper foil.

In the present embodiment, with reference to FIGS. 4, 5, and 7, the cover plate 20 is a glass the cover plate 20. The cover plate 20 comprises a first surface and a second surface. The first surface is a light exiting surface. The second surface is a backlight surface. The first bonding layer 30 contacts the second surface of the cover plate 20.

In the present embodiment, with reference to FIGS. 4, 5, and 7, the display module 100 further comprises a light shielding layer 80 disposed on an edge of the cover plate 20. The light shielding layer 80 is disposed between the cover plate 20 and the first bonding layer 30. The light shielding layer 80 is configured to shield an edge non-display region to prevent light leakage of the edge region. The light shielding layer 80 in the present embodiment is located between the cover plate 20 and the first bonding layer 30. Also, the light shielding layer 80 further extends from an edge of the second surface of the cover plate 20 to a side surface between the first surface and the second surface of the cover plate 20. Material of the light shielding layer 80 can be ink.

It should be explained that because the edge of the cover plate 20 is disposed with the light shielding layer 80, when the first bonding layer 30 of the present application, performs curing by ultraviolet, ultraviolet cannot emit to the first a region in the bonding layer 30 shielded by the light shielding layer 80, and the region is cured incompletely. Namely, a curing rate of the adhesive material in the region is low, resulting in a poor cohesion of the first bonding layer 30 in the edge region, bubbles easily occurs between the cover plate 20 and the display panel 10.

The present application can directly irradiate a surface of the first bonding layer 30 away from the cover plate 20 by ultraviolet after bonding the first bonding layer 30 and the cover plate 20 to complete the curing process of the first bonding layer 30 to prevent the technical issue of a poor cohesion in the edge region of the first bonding layer 30. Second, the second bonding layer 40 is bonded to a surface of a side of the display panel 10 toward the cover plate 20, and a surface of a side of the second bonding layer 40 away from the display panel 10 is bonded to the first bonding layer 30 to complete the bonding of the display panel 10 and the cover plate 20. Finally, the second bonding layer 40 undergoes a curing process.

In the present embodiment, when material of the second bonding layer 40 is a non-ultraviolet curable optical adhesive, a thermal curing process can be implemented to the second bonding layer 40. Therefore, both the first bonding layer 30 and the second bonding layer 40 are cured completely, and the curing rates of the first bonding layer 30 and the second bonding layer 40 are equal. Namely, cohesions of the first bonding layer 30 and the second bonding layer 40 can be equal.

With reference to FIGS. 4 and 5, when material of the second bonding layer 40 is ultraviolet curable optical adhesive, the first bonding layer 30 comprises a first sub-region 310 and a second sub-region 320. The second bonding layer 40 comprises a third sub-region 410 and a fourth sub-region 420. Orthographic projections of the first sub-region 310 and the third sub-region 410 on the light shielding layer 80 are located in the light shielding layer 80. Orthographic projections of the second sub-region 320 and the fourth sub-region 420 on a plane in which the cover plate 20 in the plane region 101 is located do not overlap the light shielding layer 80. Namely, along a top view direction of the display module, both the first sub-region 310 and the third sub-region 410 overlap the light shielding layer 80, and both the second sub-region 320 and the fourth sub-region 420 do not overlap the light shielding layer 80.

In the present embodiment, curing rates of the first sub-region 310, the second sub-region 320, and the third sub-region 410 are equal, and a curing rate of the fourth sub-region 420 is less than or equal to the curing rate of the third sub-region 410.

In the present embodiment, because of disposing the light shielding layer 80, ultraviolet cannot be emitted into a region in the second bonding layer 40 shielded by the light shielding layer 80. Namely, the fourth sub-region 420 is not cured completely, resulting in a lower curing rate of the fourth sub-region 420. Before the first bonding layer 30 is bonded to the second bonding layer 40, the curing process of the first bonding layer 30 has been completed. Therefore, curing rates of the first sub-region 310 and the second sub-region 320 in the first bonding layer 30 are the same. Also, the third sub-region 410 is not shielded by the light shielding layer 80. Thus, the third sub-region 410 is cured completely, and the curing rate of the third sub-region 410 can be the same as the curing rates of the first sub-region 310 and the second sub-region 320.

In the present embodiment, because the display module 100 only easily generates bubbles in the corner sub-regions 102b, the present application can dispose an optical adhesive with a higher curing rate in the corner sub-regions 102b to improve a cohesion of adhesive material in the corner sub-regions. For example, the curing rate of the first bonding layer 30 in the corner sub-regions 102b is greater than the curing rate of the first bonding layer 30 in the side edge sub-regions 102a, and the curing rate of the first bonding layer 30 in the corner sub-regions 102b is greater than the curing rate of the first bonding layer 30 in the plane region 101. Alternatively, the curing rate of the first bonding layer 30 in the corner sub-regions 102b is greater than the curing rate of the first bonding layer 30 in the side edge sub-regions 102a, and the curing rate of the first bonding layer 30 in the side edge sub-regions 102a is greater than the curing rate of the first bonding layer 30 in the plane region 101.

In the present embodiment, because material of the first bonding layer 30 is different from material of the cover plate 20, and material of the first bonding layer 30 is similar to material of the second bonding layer 40, a surface of an interface between the first bonding layer 30 and the second bonding layer 40 can be greater than a surface of an interface between the cover plate 20 and the first bonding layer 30. Therefore, after the first bonding layer 30 and the second bonding layer 40 is cured, a bonding force between the first bonding layer 30 and the cover plate 20 can be less than a bonding force between the second bonding layer 40 and the first bonding layer 30.

In the present embodiment, because when the first bonding layer 30 and the second bonding layer 40 are bonded, the first bonding layer 30 has already be cured. Therefore, to improve a bonding force between the display panel 10 and the cover plate 20, the present application can increase an area of the second bonding layer 40 to make the second bonding layer 40 completely cover the first bonding layer 30. For example, in the structure of FIG. 4, a boundary of the first bonding layer 30 is located in the curved surface region 102, and the boundary of the first bonding layer 30 retracts relative to a boundary of the second bonding layer 40 along a direction toward the plane region 101.

The present application, by retracting the boundary of the first bonding layer 30 relative to the boundary of the second bonding layer 40, namely increasing an area of the second bonding layer 40, increases a bonding area between the first bonding layer 30 and the second bonding layer 40, improves glutinosity between the first bonding layer 30 and the second bonding layer 40, and prevents the technical issue of separation between the display panel 10 and the cover plate 20.

In the display module 100 of the present application, a distance L1 between the boundary of the second bonding layer 40 and the boundary of the first bonding layer 30 is greater than or equal to 0 and is less than or equal to 0.5 microns. For example, in the structure of FIG. 4, a boundary of the second bonding layer 40 and the first bonding layer 30 on the same side comprises the distance L1. Also, because both the first bonding layer 30 and the second bonding layer 40 are in a curved state in the corner sub-regions 102b, the distance L1 between the boundary of the second bonding layer 40 and the boundary of the first bonding layer 30 of the present application can be an arc length. For example, in the cross-section in FIG. 4, an arc length L1 between the boundary of the second bonding layer 40 and the boundary of the first bonding layer 30 can be greater than or equal to 0 and is less than or equal to 0.5 microns.

Also, with reference to FIG. 5, the boundary of the first bonding layer 30 is located in the curved surface region 102, and the boundary of the first bonding layer 30 protrudes relative to the boundary of the second bonding layer 40 along a direction away from the plane region 101.

It should be explained that to avoid a risk of adhesive overflow occurring in the first bonding layer 30, the boundary of the first bonding layer 30 cannot protrude out from the boundary of the second bonding layer 40 excessively. For example, a distance L2 between the boundary of the second bonding layer 40 and the boundary of the first bonding layer 30 is greater than 0 and is less than or equal to 0.1 microns.

In the present embodiment, because the first bonding layer 30 would be squeezed when the first bonding layer 30 and the second bonding layer 40 are bonded, and an outer boundary of the first bonding layer 30 would expand outwardly, to prevent adhesive overflow, the boundary of the first bonding layer 30 retracts relative to the boundary of the second bonding layer 40 during manufacturing to reserve a certain adhesive overflow space in advance. In a final product, according to the reserved adhesive overflow space in advance, the boundary of the first bonding layer 30 can retract or protrude relative to the boundary of the second bonding layer 40. For example, in FIG. 4, the boundary of the first bonding layer 30 retracts relative to the boundary of the second bonding layer 40 along a direction toward the plane region 101. For example, in FIG. 5, the boundary of the first bonding layer 30 retracts relative to the boundary of the second bonding layer 40 along a direction away from the plane region 101.

In the present embodiment, the boundary of the first bonding layer 30 and the boundary of the second bonding layer 40 can be located in the same plane, namely, the boundary of the first bonding layer 30 is flush with the boundary of the second bonding layer 40 can.

Because a cohesion of material is not only relevant to properties of the material but also is relevant to a thickness of the material, the thickness of the material is positively correlated with the cohesion of the material. For example, a thickness of the first bonding layer 30 is greater than or equal to a thickness of the second bonding layer 40.

The present application, by increasing the thickness of the first bonding layer 30, increases the cohesion of the first bonding layer 30 to further improve a strength of the first bonding layer 30 such that a rebound force exerted by the first bonding layer 30 against the module structure in the corner sub-regions 102b is increased to ease the issue of bubbles easily occurring after bonding of the Gaussian curved surface of the conventional quad-curved surface screen.

In the present embodiment, a thickness of the first bonding layer 30 ranges from 25 microns to 200 microns, and a thickness of the second bonding layer 40 thickness ranges from 25 microns to 200 microns.

With reference to FIG. 4, because the second bonding layer 40, before cured, is formed on a side of the display panel 10 near the cover plate 20. Also, a coating area of the adhesive layer cannot be precisely controlled. Thus, the present application, before the display panel 10 and the backplate are cut, coats the second bonding layer 40 on a surface of the display panel 10 toward a side of the cover plate 20, and then cut the second bonding layer 40, the display panel 10, and the backplate simultaneously. Therefore, the boundary of the second bonding layer 40, the boundary of the display panel 10 and the boundary of the backplate of the present application can be located in the same plane.

In the present embodiment, with reference to FIG. 4, because the polarizer 50 is generally disposed between the second bonding layer 40 and the display panel 10. Therefore, in the present application, the boundary of the polarizer 50, the boundary of the second bonding layer 40, the boundary of the display panel 10, and the boundary of the backplate can be located in the same plane.

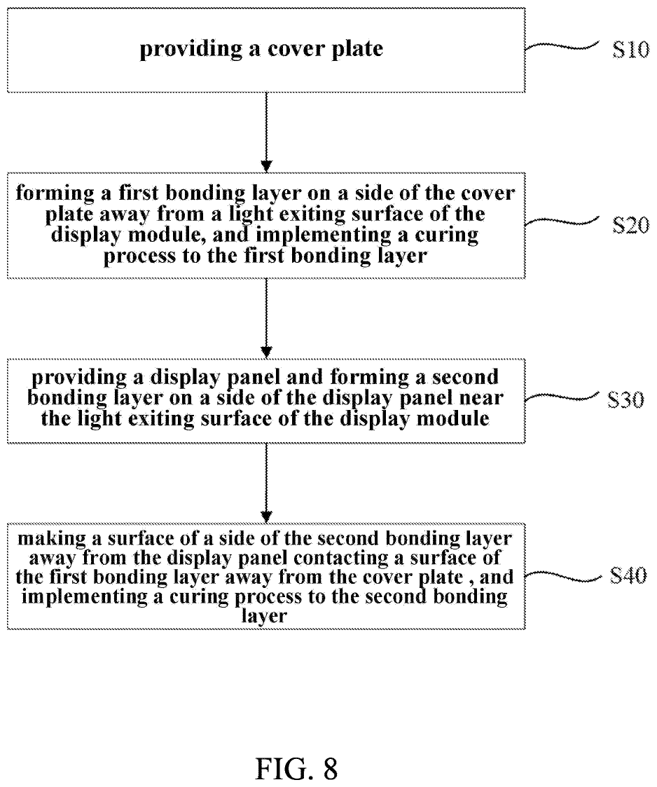

With reference to FIG. 8, the present application also sets forth a method for manufacturing a display module 100. The display module 100 comprises a plane region 101 and a curved surface region 102 located on an outer periphery of the plane region 101, and the curved surface region 102 comprises a plurality of side edge sub-regions 102a located on a peripheral side of the plane region 101 and corner sub-regions 102b each of which is located between adjacent two of the side edge sub-regions 102a, and the method comprises steps as follows:

A step S10 comprises providing a cover plate 20.

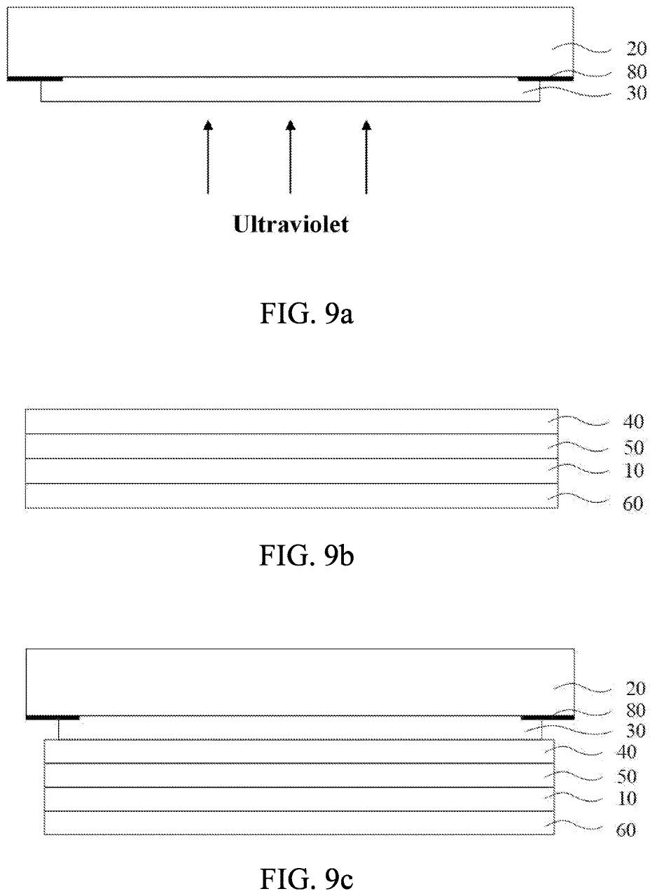

With reference to FIGS. 9a and 4, the cover plate 20 is a glass the cover plate 20, the cover plate 20 comprises a first surface and a second surface. The first surface is a light exiting surface, and the second surface is a backlight surface.

In the structure of FIG. 9a, a light shielding layer 80 is also disposed on the edge of the cover plate 20. The light shielding layer 80 is configured to shield the edge non-display region to prevent light leakage in the edge region. The light shielding layer 80 further extends from an edge of a second surface of the cover plate 20 to a side surface between the first surface and the second surface of the cover plate 20. Material of the light shielding layer 80 can be ink.

A step S20 comprises forming a first bonding layer 30 on a side of the cover plate 20 away from a light exiting surface of the display module 100, and implementing a curing process to the first bonding layer 30. The first bonding layer 30 is at least disposed in in the corner sub-regions 102b.

With reference to FIG. 9a, material of the first bonding layer 30 of the present application can comprise an ultraviolet curable optical adhesive, namely, it can utilize ultraviolet to cure the first bonding layer 30.

In the present embodiment, because of existence of the light shielding layer 80, ultraviolet cannot enter the first bonding layer 30 covered by the light shielding layer 80 when emitted to the first bonding layer 30 from the first surface of the cover plate 20, resulting in incompletely curing of the first bonding layer 30. Therefore, the present application can implement ultraviolet irradiation directly to a surface of the first bonding layer 30 away from the cover plate 20 after bonding the first bonding layer 30 and the cover plate 20 to complete the curing process of the first bonding layer 30, avoiding the technical issue of a lower the curing rate of the first bonding layer 30 in the edge region.

A step S30 comprises providing a display panel 10 and forming a second bonding layer 40 on a side of the display panel 10 near the light exiting surface of the display module 100. The second bonding layer 40 is at least disposed in the corner sub-regions 102b.

With reference to FIG. 9b, material of the second bonding layer 40 comprises an ultraviolet curable optical adhesive and a non-ultraviolet curable optical adhesive.

In the present embodiment, the display module 100 further comprises a backplate layer 60 disposed on a side of the display panel 10 away from the cover plate 20 and a polarizer 50 disposed between the second bonding layer 40 and the display panel 10.

In the present embodiment, because the second bonding layer 40 is formed on a side of the display panel 10 near the cover plate 20 in advance before cured, and a coating area of the adhesive layer cannot be controlled precisely, the present application coats the second bonding layer 40 on a side of the display panel 10 toward the cover plate 20 surface before cutting the display panel 10 and the backplate, and then cut the second bonding layer 40, the display panel 10, and the backplate simultaneously. Therefore, the boundary of the second bonding layer 40, the boundary of the polarizer 50, the boundary of the display panel 10, and the boundary of the backplate of the present application can be located in the same plane.

A step S40 comprises making a surface of a side of the second bonding layer 40 away from the display panel 10 contacting a surface of the first bonding layer 30 away from the cover plate 20, and implementing a curing process to the second bonding layer 40.

With reference to FIG. 9c, after the second bonding layer 40 is bonded to the first bonding layer 30, a curing process can be implemented directly on the second bonding layer 40 to complete bonding of the display panel 10 and the cover plate 20.

In the present embodiment, when material of the second bonding layer 40 is a non-ultraviolet curable optical adhesive, a thermal curing process can be utilized to implement the curing process to the second bonding layer 40. Therefore, both the first bonding layer 30 and the second bonding layer 40 are cured completely, and the curing rates of the first bonding layer 30 and the second bonding layer 40 can be equal.

In the present embodiment, with reference to FIG. 4, when material of the second bonding layer 40 is an ultraviolet curable optical adhesive, the first bonding layer 30 comprises a first sub-region 310 and a second sub-region 320, and the second bonding layer 40 comprises a third sub-region 410 and a fourth sub-region 420. Orthographic projections of the first sub-region 310 and the third sub-region 410 on the light shielding layer 80 are located in the light shielding layer 80, and orthographic projections of the second sub-region 320 and the fourth sub-region 420 on the light shielding layer 80 do not overlap the light shielding layer 80. Also, the curing rates of the first sub-region 310, the second sub-region 320, and the third sub-region 410 are equal, the curing rate of the fourth sub-region 420 is less than or equal to the curing rate of the third sub-region 410.

In the present embodiment, because of disposing the light shielding layer 80, ultraviolet cannot be emitted to a region shielded by the light shielding layer 80 in the second bonding layer 40, i.e., the fourth sub-region 420. The region is cured incompletely, and a curing rate is low, resulting in a poor cohesion of the fourth sub-region 420. Before the first bonding layer 30 is bonded to the second bonding layer 40, the curing process of the first bonding layer 30 has been completed. Therefore, the curing rates of the first sub-region 310 and the second sub-region 320 in the first bonding layer 30 are the same. Also, the third sub-region 410 is not shielded by the light shielding layer 80. Therefore, the third sub-region 410 is completely cured, the curing rate of the third sub-region 410 can be the same as the curing rate of the first sub-region 310 and the second sub-region 320.

The present application also sets forth a display device comprising a terminal main body and the above display module. Terminal main body and display module are assembled as a whole. The terminal main body can be a device such as a circuit board bonded to the display panel and a cover plate covering the display panel. The display device can comprise an electronic apparatus such as cell phone, television, notebook, etc.

In the above-mentioned embodiments, the descriptions of the various embodiments are focused. For the details of the embodiments not described, reference may be made to the related descriptions of the other embodiments.

The display module, the manufacturing method thereof, and the display device thereof provided by the embodiment of the present application, are described in detail as above. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

What is claimed is:

1. A display module, comprising a plane region and a curved surface region located on an outer periphery of the plane region, and the curved surface region comprising a plurality of side edge sub-regions located on a peripheral side of the plane region and corner sub-regions each of which is located between adjacent two of the side edge sub-regions, wherein the display module comprises:
a display panel;
a cover plate disposed on a side of the display panel; and
a first bonding layer located between the display panel and the cover plate, wherein the first bonding layer is at least disposed in the corner sub-regions, and the first bonding layer contacts the cover plate; and
a second bonding layer located between the display panel and the cover plate, wherein the second bonding layer is at least disposed in the corner sub-regions, and a surface of a side of the second bonding layer near the cover plate contacts the first bonding layer;
wherein a curing rate of the first bonding layer is greater than or equal to a curing rate of the second bonding layer.

2. The display module according to claim 1, wherein a bonding force between the first bonding layer and the cover plate is less than a bonding force between the second bonding layer and the first bonding layer.

3. The display module according to claim 1, wherein a boundary of the first bonding layer is located in the curved surface region, and the boundary of the first bonding layer retracts relative to a boundary of the second bonding layer along a direction toward the plane region.

4. The display module according to claim 3, wherein a distance between the boundary of the second bonding layer and the boundary of the first bonding layer is greater than or equal to 0 and is less than or equal to 0.5 microns.

5. The display module according to claim 1, wherein a boundary of the first bonding layer is located in the curved surface region, and the boundary of the first bonding layer protrudes relative to a boundary of the second bonding layer along a direction away from the plane region.

6. The display module according to claim 5, wherein a distance between the boundary of the second bonding layer and the boundary of the first bonding layer is greater than 0 and is less than or equal to 0.1 microns.

7. The display module according to claim 1, wherein a thickness of the first bonding layer is greater than or equal to a thickness of the second bonding layer.

8. The display module according to claim 7, wherein the thickness of the first bonding layer ranges from 25 microns to 200 microns, and the thickness of the second bonding layer ranges from 25 microns to 200 microns.

9. The display module according to claim 1, wherein the display module further comprises a light shielding layer located on an edge of the cover plate, and the light shielding layer is disposed between the cover plate and the first bonding layer;
wherein at least a portion of the first bonding layer overlaps the light shielding layer.

10. The display module according to claim 9, wherein the first bonding layer comprises a first sub-region and a second sub-region, the second bonding layer comprises a third sub-region and a fourth sub-region, orthographic projections of the first sub-region and the third sub-region on the light shielding layer are located in the light shielding layer, orthographic projections of the second sub-region and the fourth sub-region on a plane in which the cover plate is located do not overlap the light shielding layer, and curing rates of the first sub-region, the second sub-region, and the third sub-region are equal.

11. The display module according to claim 10, wherein material of the first bonding layer is equal to material of the first bonding layer;
wherein a curing rate of the fourth sub-region is less than a curing rate of the third sub-region.

12. The display module according to claim 11, wherein material of the first bonding layer comprises ultraviolet curable optical adhesive, and material of the second bonding layer comprises an ultraviolet curable optical adhesive.

13. The display module according to claim 10, wherein material of the first bonding layer is different from material of the first bonding layer;
wherein the curing rate of the fourth sub-region is equal to the curing rate of the third sub-region.

14. The display module according to claim 13, wherein material of the first bonding layer comprises an ultraviolet curable optical adhesive, material of the second bonding layer comprises a non-ultraviolet curable optical adhesive.

15. The display module according to claim 1, wherein the display module further comprises a backplate disposed on a side of the display panel away from the cover plate, and a boundary of the second bonding layer, a boundary of the display panel, and a boundary of the backplate are located in in a same plane.

16. The display module according to claim 15, wherein the display module further comprises a polarizer disposed between the display panel and the second bonding layer, and the boundary of the second bonding layer, a boundary of the polarizer, the boundary of the display panel, and the boundary of the backplate are located in a same plane.

17. A display module manufacturing method, comprising a plane region and a curved surface region located on an outer periphery of the plane region, and the curved surface region comprising a plurality of side edge sub-regions located on a peripheral side of the plane region and corner sub-regions each of which is located between adjacent two of the side edge sub-regions, wherein the display module manufacturing method comprises:
providing a cover plate;
forming a first bonding layer on a side of the cover plate away from a light exiting surface of the display module, and implementing a curing process to the first bonding layer, wherein the first bonding layer is at least disposed in the corner sub-regions;
providing a display panel, forming a second bonding layer on a side of the display panel near the light exiting surface of the display module, wherein the second bonding layer is at least disposed in the corner sub-regions; and
making a surface of the second bonding layer away from the display panel contacting a surface of the first bonding layer away from the cover plate, and implementing a curing process to the second bonding layer;
wherein a curing rate of the first bonding layer is greater than or equal to a curing rate of the second bonding layer.

18. A display device, comprising a display module, the display module comprising a plane region and a curved surface region located on an outer periphery of the plane region, and the curved surface region comprising a plurality of side edge sub-regions located on a peripheral side of the plane region and corner sub-regions each of which is located between adjacent two of the side edge sub-regions:
wherein the display module comprises:
a display panel;
a cover plate disposed on a side of the display panel; and
a first bonding layer located between the display panel and the cover plate, wherein the first bonding layer is at least disposed in the corner sub-regions, and the first bonding layer contacts the cover plate; and
a second bonding layer located between the display panel and the cover plate, wherein the second bonding layer is at least disposed in the corner sub-regions, and a surface of a side of the second bonding layer near the cover plate contacts the first bonding layer;
wherein a curing rate of the first bonding layer is greater than or equal to a curing rate of the second bonding layer.

19. The display device according to claim 18, wherein a boundary of the first bonding layer is located in the curved surface region, and the boundary of the first bonding layer retracts relative to a boundary of the second bonding layer along a direction toward the plane region.

20. The display device according to claim 19, wherein the display module further comprises a light shielding layer located on an edge of the cover plate, the light shielding layer is disposed between the cover plate and the first bonding layer, and at least a portion of the first bonding layer overlaps the light shielding layer;
wherein the first bonding layer comprises a first sub-region and a second sub-region, the second bonding layer comprises a third sub-region and a fourth sub-region, orthographic projections of the first sub-region and the third sub-region on the light shielding layer are located in the light shielding layer, orthographic projections of the second sub-region and the fourth sub-region on a plane in which the cover plate are located do not overlap the light shielding layer, curing rates of the first sub-region, the second sub-region, and the third sub-region are equal, and a curing rate of the fourth sub-region is less than a curing rate of the third sub-region.
